(19) United States
(12) Patent Application Publication
(10) Pub. No.: US 2008/0054401 A1
(43) Pub. Date: Mar. 6, 2008

(54) Capacitor structure of semiconductor device

(75) Inventor: Chan Ho Park, Seoul (KR)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: DONGBU HITEK CO., LTD.

(21) Appl. No.: 11/892,752

(22) Filed: Aug. 27, 2007

(30) Foreign Application Priority Data
Aug. 30, 2006 (KR) 10-2006-0082705

(51) Int. Cl. H01L 29/00

(52) U.S. Cl. 257/532; 257/E29.001

(57) ABSTRACT

A capacitor structure of a semiconductor device includes: a plurality of first metal elements connected in a vertical direction by first vias; a plurality of second metal elements connected in the vertical direction by second vias and arranged alternately with the first metal elements in a horizontal direction; dielectric materials formed between the first and the second metal elements; and a branch unit for supplying current to each layer of the capacitor structure and grounding each layer of the capacitor structure, each layer having the first and the second metal elements disposed in an identical horizontal plane, wherein one ends of the first metal elements and one ends of the second metal elements are extended in opposite horizontal directions to form a first and a second extension unit, respectively; and the first and the second extension units are connected to the branch unit.

### RELATED APPLICATION

This application claims the benefit of priority to Korean Patent Application No. 10-2006-0082705, filed on Aug. 30, 2006, which is incorporated herein by reference in its entirety.

### TECHNICAL FIELD

The present invention relates, in general, to a capacitor structure of a semiconductor device and, more particularly, to a capacitor structure of a semiconductor device with an improved matching characteristic.

### DESCRIPTION OF THE RELATED ART

A capacitor is one of semiconductor devices to which integrated circuits (ICs) can be applied. In the IC industry, various types of capacitors for use in both complementary metal oxide semiconductor (CMOS) and bipolar CMOS devices have been developed. Two types of capacitors in advanced IC industry include metal oxide metal (MOM) and metal insulator metal (MIM) capacitors. With these devices, the IC industry can obtain accurate capacitance values for analog circuits. The advantage of the MOM and MIM capacitors is that capacitors can have a high capacitance in a narrow area. MOM capacitors are generally formed on a silicon substrate by depositing a metal layer serving as one of the electrodes of the capacitors. A capacitor dielectric material is then deposited on titanium nitride (TiN). Then a metal layer serving as an electrode of another capacitor is deposited on the dielectric layer. Several layers are patterned and etched to form a preferred capacitor structure. MOM and MIM capacitors are frequently formed in apertures by using dielectric materials.

FIG. 1 is a schematic perspective view of a conventional capacitor structure, and FIG. 2 is a plan view of the capacitor structure shown in FIG. 1.

Referring to FIGS. 1 and 2, a capacitor structure 10 includes first metal elements 11 and second metal elements 12. First metal elements 11 and second metal elements 12 are engaged with each other in the X and Y axes. Dielectric material 13 is formed between first metal element 11 and second metal element 12. Dielectric material 13 is formed from oxide.

A power supply line 14 is disposed in first metal element 11 of the lowest layer, and a ground unit 15 is disposed in second metal element 12 of the lowest layer. Vias 16, providing a signal current path of power supply line 14, connect first metal elements 11 and second metal elements 12.

In the conventional capacitor structure 10, power supply line 14 is disposed only at the lowest layer as described above. Thus, in transferring a current signal up to the capacitor layer of the highest layer, resistance is generated from the metal element of each layer, making it difficult to produce device products having the same specification. These types of capacitors can be fabricated at low cost, but have rarely used because of a qualitative problem such as mismatching.

### SUMMARY

Embodiments consistent with the present invention provide a capacitor structure of a semiconductor device in which extension units extending from every layer of the capacitor structure are connected to a branch unit that is supplied with power or grounded so that a sufficient current can be supplied to each layer rapidly, preventing mismatching and enabling the use of cheap MOM capacitors.

Consistent with an embodiment of the present invention, there is provided a capacitor structure of a semiconductor device including:

a plurality of first metal elements connected with each other in a vertical direction by first vias;

a plurality of second metal elements connected with each other in the vertical direction by second vias and arranged alternately with the first metal elements in a horizontal direction;

dielectric materials formed between the first metal elements and the second metal elements; and

a branch unit for supplying current to each layer of the capacitor structure and grounding each layer of the capacitor structure, each layer having the first metal elements and the second metal elements lying in an identical horizontal plane,

wherein one ends of the first metal elements are extended in one horizontal direction to form a first extension unit and one ends of the second metal elements are extended in an opposite horizontal direction to form a second extension unit; and

wherein the first extension unit and the second extension unit are connected to the branch unit.

### BRIEF DESCRIPTION OF THE DRAWINGS

The above and other features of the present invention will become apparent from the following description of embodiments given in conjunction with the accompanying drawings.

FIG. 1 is a schematic perspective view of a conventional capacitor structure;

FIG. 2 is a plan view of the capacitor structure shown in FIG. 1;

FIG. 3 is a schematic perspective view of a capacitor structure consistent with an embodiment of the present invention; and

FIG. 4 is a plan view of the capacitor structure shown in FIG. 3.

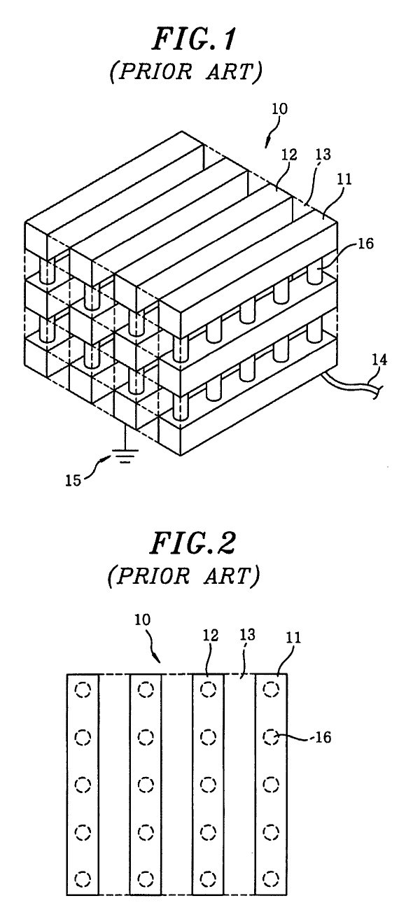

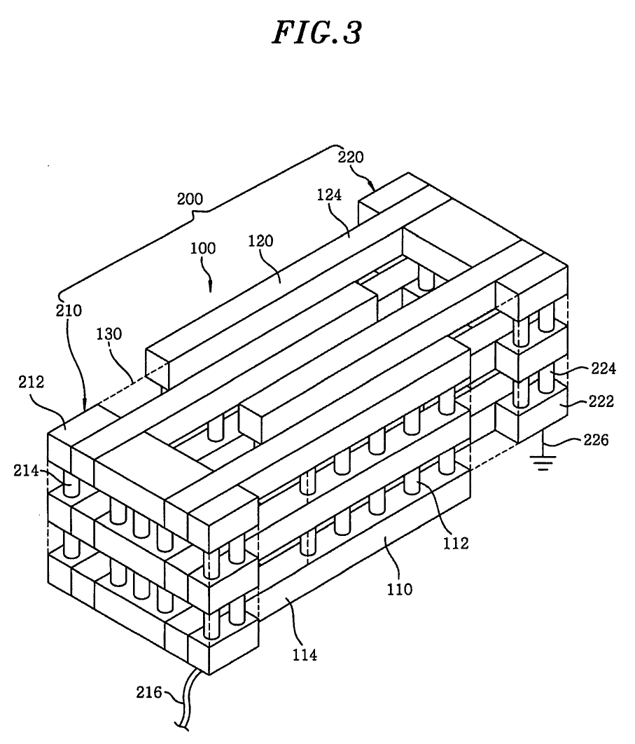

### DETAILED DESCRIPTION

Hereinafter, embodiments of the present invention will be described in detail with reference to the accompanying drawings.

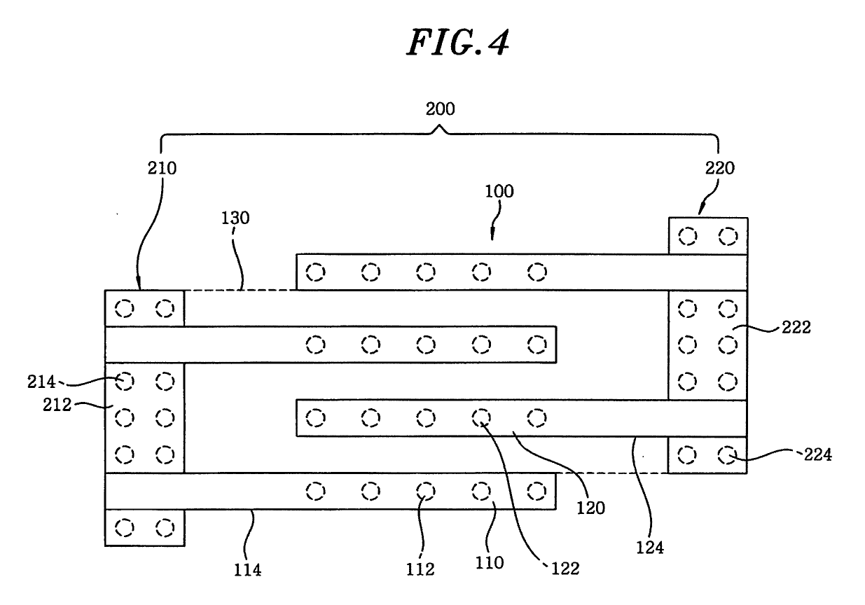

FIG. 3 is a schematic perspective view of a capacitor structure consistent with an embodiment of the present invention, and FIG. 4 is a plan view of the capacitor structure shown in FIG. 3.

Referring to FIGS. 3 and 4, a capacitor structure 100 includes first metal elements 110 and second metal elements 120, which are repeatedly and alternately arranged in a horizontal direction, and dielectric materials 130 are formed between first metal elements 110 and second metal elements 120.

First metal elements 110 are stacked in plural numbers in a vertical direction. First metal elements 110, which are disposed vertically, are connected by a plurality of vias 112. Dielectric materials 130 included in vias 112 can be preferably disposed between first metal elements 110, which are disposed vertically. Dielectric material 130 can be formed from oxide.

Further, second metal elements 120 are stacked in plural numbers in the vertical direction. Second metal elements 120 are connected by vias 122. Dielectric materials 130 made of oxide are disposed in vias 122.

Dielectric materials 130 are also disposed between first metal elements 110 and second metal elements 120, which are repeatedly and alternately disposed in the horizontal direction, and between branch units 200 described below.

One ends of first metal elements 110 and second metal elements 120 form first extension unit 114 and second extension unit 124, respectively, which extend in opposite horizontal directions. In other words, first extension unit 114 of first metal elements 110 and second extension unit 124 of second metal elements 120 extend in opposite directions. First extension unit 114 and second extension unit 124 are connected to branch unit 200. Branch unit 200 supplies current to the respective layers comprised of first metal elements 110 and second metal elements 120 or grounds the layers.

A layer, in a horizontal direction, includes first metal elements 110, dielectric materials 130, and second metal elements 120. Branch unit 200 is connected to the layer.

Branch unit 200 supplies the current to each layer of capacitor structure 100 or grounds the layer.

Branch unit 200 includes a power supply branch 210 and a ground branch 220. Capacitor structure 100 is between power supply branch 210 and ground branch 220.

Thus, power supply branch 210 may be connected to first extension unit 114 of first metal elements 110 or second extension unit 124 of second metal elements 120, and supplies power through a power supply line 216. Ground branch 220 may be connected to first extension unit 114 of first metal elements 110 or second extension unit 124 of second metal elements 120, and provides ground through a ground line 226.

As shown in FIGS. 3 and 4, first extension unit 114 of first metal elements 110 is connected to power supply branch 210, and second extension unit 124 of second metal elements 120 is connected to ground branch 220. Other configurations may also be used.

Power supply branch 210 and ground branch 220 include respective metal layers 212 and 222 vertically stacked with respective vias 214 and 224 and dielectric materials 130 placed therebetween. First extension unit 114 and second extension unit 124 are inserted into each of metal layers 212 and 222.

Power supply line 216 is connected to a lowest layer of metal layers 212 of power supply branch 210. Ground line 226 is connected to a lowest layer of metal layers 222 of ground branch 220. Vias 214 of power supply branch 210 are for signal power and vias 224 of ground branch 220 are for ground.

An operation of the capacitor structure of the semiconductor device constructed as above will be described below in detail.

First extension unit 114 of first metal elements 110 is connected to metal layer 212 of power supply branch 210, and second extension unit 124 of second metal elements 120 is connected to metal layers 222 of ground branch 220 at both sides of capacitor structure 100.

In this state, if power is supplied through power supply line 216 connected to power supply branch 210, a transmission signal is transmitted along vias 214 of each of metal layers 212, and the current is supplied to first metal elements 110 of each layer connected along first extension unit 114.

Thus, current that is not affected by the resistance of other metal layers can be supplied to first metal elements 110 of each layer sufficiently and rapidly, so that devices having the same specification can be obtained.

Further, the current returned from first metal elements 110 is induced to ground branch 220 connected to second extension unit 124 of second metal elements 120. The induced current flows into ground line 226 through vias 224 of each of metal layers 222.

As mentioned above, consistent with the present invention, in order to solve the problem that devices are mismatched since a sufficient and constant current is not supplied to each layer in the prior art, branch unit 200 is disposed to supply current to each layer.

Furthermore, MOS capacitors, which are cheap and have a simple construction, can be used instead of MIM capacitor, which are expensive and have a complicated construction.

The present invention can also be applied to a damascene process as well as a metal etching process.

As described above, consistent with the capacitor structure of the semiconductor device of the present invention, the extension unit extending from each layer of the capacitor structure is connected to the branch unit for supplying power or providing ground, so that a sufficient current can be supplied to each layer rapidly. Accordingly, there are advantages in that mismatching can be prevented and cheap MOM capacitors can be used.

While the invention has been shown and described with respect to several embodiments, it will be understood by those skilled in the art that various changes and modifications may be made without departing from the scope of the invention as defined in the following claims.

What is claimed is:

1. A capacitor structure of a semiconductor device comprising:
a plurality of first metal elements connected with each other in a vertical direction by first vias;
a plurality of second metal elements connected with each other in the vertical direction by second vias and arranged alternately with the first metal elements in a horizontal direction;
dielectric materials formed between the first and the second metal elements; and
a branch unit for supplying current to each layer of the capacitor structure and grounding each layer of the capacitor structure, each layer having the first metal elements and the second metal elements disposed in an identical horizontal plane,
wherein one ends of the first metal elements are extended in one horizontal direction to form a first extension unit and one ends of the second metal elements are extended in an opposite horizontal direction to form a second extension unit; and
wherein the first extension unit and the second extension unit are connected to the branch unit.

2. The capacitor structure of claim 1, wherein the branch unit includes:
a power supply branch, connected to the first or the second extension unit, for supplying power to the capacitor structure; and
a ground branch, connected to the first or the second extension unit, for grounding the capacitor structure.

3. The capacitor structure of claim 2, wherein
the power supply branch includes a plurality of first metal layers stacked vertically with third vias and the dielectric materials disposed therebetween;
the ground branch includes a plurality of second metal layers stacked vertically with fourth vias and the dielectric materials disposed therebetween; and
the first or the second extension unit is inserted into each of the first or the second metal layers.

4. The capacitor structure of claim 2, wherein the power supply branch is disposed at one side of the capacitor structure and the ground branch is disposed at an opposite side of the capacitor structure.

5. The capacitor structure of claim 3, wherein the first metal layers are connected to a power supply line and the second metal layers are connected to a ground line.
